(19) United States
(12) Patent Application Publication
(10) Pub. No.: US 2015/0187615 A1
(43) Pub. Date: Jul. 2, 2015

(54) COMPONENT OF A PLASMA PROCESSING APPARATUS INCLUDING AN ELECTRICALLY CONDUCTIVE AND NONMAGNETIC COLD SPRAYED COATING

(71) Applicant: Lam Research Corporation, Fremont, CA (US)

(72) Inventors: John Daugherty, Fremont, CA (US); Hong Shih, Walnut, CA (US); Anthony Amadio, San Mateo, CA (US); Tom Stevenson, Morgan Hill, CA (US); Lin Xu, Katy, TX (US); John Michael Kerns, Livermore, CA (US); Robert Griffith O'Neill, Hayward, CA (US); Sonia Castillo, Hayward, CA (US)

(21) Appl. No.: 14/578,979

(22) Filed: Dec. 22, 2014

Related U.S. Application Data
(60) Provisional application No. 61/922,186, filed on Dec. 31, 2013.

(51) Int. Cl. H01L 21/67; H01L 21/02; C25D 11/02; H01L 21/3065; C23C 24/04; C23C 22/73

(52) U.S. Cl. CPC H01L 21/67069; C23C 24/04; C23C 22/73; H01L 21/67017; C25D 11/02; H01L 21/3065; H01L 21/02274

(57) ABSTRACT

A semiconductor plasma processing apparatus used to process semiconductor components comprises a plasma processing chamber, a process gas source in fluid communication with the plasma processing chamber for supplying a process gas into the plasma processing chamber, a RF energy source adapted to energize the process gas into the plasma state in the plasma processing chamber, and a vacuum port for exhausting process gas from the plasma processing chamber. The semiconductor plasma processing apparatus further comprises at least one component wherein the component has a body which has a relative magnetic permeability of about 70,000 or greater and a cold sprayed electrically conductive and nonmagnetic coating on a surface of the body wherein the coating has a thickness greater than the skin depth of a RF current configured to flow therethrough during plasma processing.

### CROSS REFERENCE TO RELATED APPLICATION

This application claims priority under 35 U.S.C. §119(e) to U.S. Provisional Application No. 61/922,186, filed on Dec. 31, 2013, the entire content of which is incorporated herein by reference thereto.

### FIELD OF THE INVENTION

The present invention relates to components of semiconductor plasma processing apparatuses, and more specifically for a component which includes an electrically conductive and nonmagnetic coating overlying a μ-metal body for use in a semiconductor plasma processing apparatus.

### BACKGROUND

Plasma processing apparatuses are used to process semiconductor substrates by techniques including etching, plasma enhanced physical vapor deposition (PEPVD), chemical vapor deposition (CVD), plasma enhanced chemical vapor deposition (PECVD), atomic layer deposition (ALD, ion implantation, and resist removal. Due to shrinking feature sizes and the implementation of new materials, improvement in plasma processing apparatuses to control the conditions of the plasma processing is required.

### SUMMARY

Disclosed herein is a semiconductor plasma processing apparatus used to process semiconductor components. The plasma processing apparatus comprises a plasma processing chamber, a process gas source in fluid communication with the plasma processing chamber for supplying a process gas into the plasma processing chamber, a RF energy source adapted to energize the process gas into the plasma state in the plasma processing chamber, and a vacuum port for exhausting process gas from the plasma processing chamber. The semiconductor plasma processing apparatus further comprises at least one component wherein the component has a body which has a relative magnetic permeability of about 70,000 or greater and a cold sprayed electrically conductive and nonmagnetic coating on a surface of the body, wherein the coating has a thickness greater than the skin depth of a RF current configured to flow therethrough during plasma processing.

Also disclosed herein is a component of a semiconductor plasma processing apparatus. The component comprises a body which has a relative magnetic permeability of about 70,000 or greater and a cold sprayed electrically conductive and nonmagnetic coating on a surface of the body wherein the coating has a thickness greater than the skin depth of a RF current configured to flow therethrough during plasma processing.

Further disclosed herein is a method of forming a component of a semiconductor plasma processing apparatus. The method comprises cold spraying an electrically conductive and nonmagnetic material on a surface of a body of the component wherein the body has a relative magnetic permeability of about 70,000 or greater. The cold sprayed coating is formed on the body of the component such that the thickness of the coating is greater than the skin depth of a RF current configured to flow therethrough.

### BRIEF DESCRIPTION OF THE DRAWING FIGURES

FIG. 1A illustrates magnetic field lines of an unshielded region in an ambient magnetic field, and FIG. 1B illustrates magnetic field lines of a shielded region in an ambient magnetic field.

FIG. 2 illustrates a cross section of a component of a plasma processing apparatus which includes a body and a cold sprayed electrically conductive and nonmagnetic coating on a surface of the body.

FIG. 3 illustrates an exemplary embodiment of an inductively coupled plasma etching chamber in which embodiments of the component can be installed.

### DETAILED DESCRIPTION

Disclosed herein is a component of a semiconductor plasma processing apparatus. The component comprises a body formed of a material having a high magnetic permeability and an electrically conductive and nonmagnetic coating on a surface of the body, wherein the electrically conductive and nonmagnetic coating is deposited on the surface of the body with a cold spray process. The component can preferably provide magnetic shielding while allowing a RF current to flow through the cold sprayed coating, such as an RF current of about 400 KHz to 60 MHz. The semiconductor plasma processing apparatus preferably includes a vacuum chamber, which may be a plasma etching or deposition chamber (herein referred to as “vacuum chamber”) of a semiconductor plasma processing apparatus. In the following description, numerous specific details are set forth in order to provide a thorough understanding of the present embodiments. It will be apparent, however, to one skilled in the art that the present embodiments may be practiced without some or all of these specific details. In other instances, well known process operations have not been described in detail in order not to unnecessarily obscure present embodiments disclosed herein.

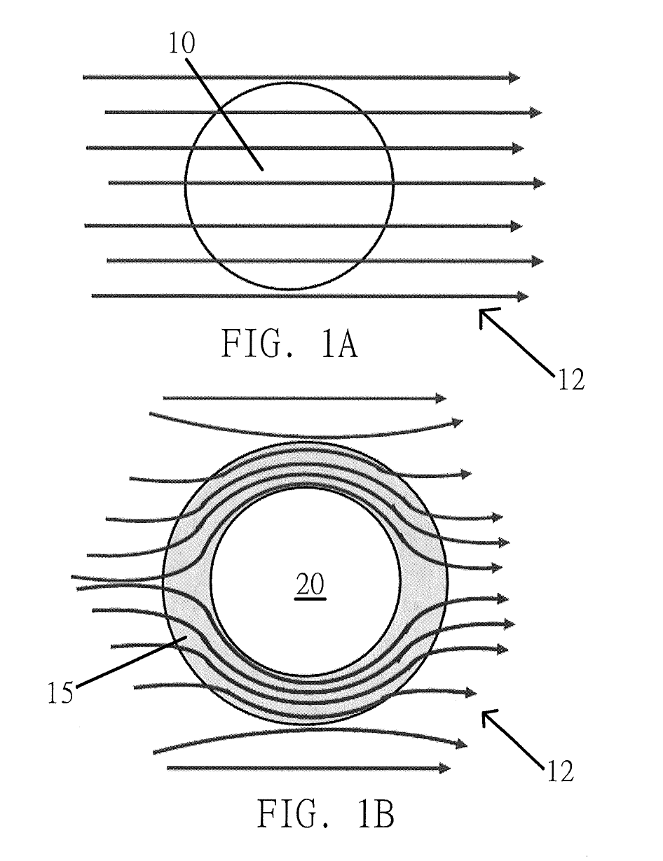

Magnetic fields generated in and around plasma processing chambers from sources such as Earth's magnetic field, motors, power supplies, transformers, RF path members which support a RF current during processing, electrical connectors, and the like, can cause skewed etch rates across the surface of a semiconductor substrate (i.e. skewed substrate etch rates and/or process drift) during plasma processing of semiconductor substrates, and therefore it is preferable that such magnetic fields are shielded from the internal plasma generation space (i.e. vacuum space) of the plasma processing chamber (i.e. vacuum chamber). Magnetic shielding provides a path for magnetic field lines formed inside or outside of the vacuum space of the plasma processing apparatus to travel along such that effects (e.g. interference) of those formed magnetic field lines are reduced or removed with respect to the plasma processing space, i.e. a vacuum space, of the plasma processing apparatus. For example, the magnetic shielding can allow magnetic fields, such as those formed by an antenna of an inductively coupled plasma processing apparatus, to be formed within the vacuum chamber thereof, without extraneous magnetic field lines, such as those formed by a transistor or motor located outside of the vacuum chamber, to interfere therewith. To reduce the effects of magnetic fields on semiconductor substrate processing, ferromagnetic materials, such as μ-metals (i.e. nickel-iron alloys) can be used to form bodies of respective components which have magnetic shielding properties (i.e. can provide a magnetic field line path), wherein the components can be used to form a magnetic shields. For example, FIG. 1A illustrates magnetic field lines of an unshielded region 10 in an ambient magnetic field 12, while FIG. 1B illustrates a μ-metal magnetic shield 15 which provides a path for magnetic field lines to travel around a shielded region 20 in the ambient magnetic field 12.

However, since the body of the component has a very high magnetic permeability, the skin depth (as explained below) of a RF current flowing through the component is very thin. This leads to unacceptable resistive power loss when a RF current is flowed through the component, thus impairing semiconductor processing uniformity for certain applications, such as those wherein it is desirable that RF current flows through the component. For example, in an embodiment it may be desirable to electrically ground the component such that the component can terminate an electric field, or alternatively, the component can be configured to become RF hot when ungrounded in an electric field. Therefore, the body of the component which is formed of a material with high magnetic permeability (e.g. a ferromagnetic material), such as a n-metal body, preferably includes a cold sprayed electrically conductive and nonmagnetic coating on a surface of thereof, preferably an interior facing surface thereof, or alternatively, on each exposed surface thereof, such that the cold sprayed coating can support a RF current configured to flow therethrough. The electrically conductive and nonmagnetic cold sprayed coating is preferably formed of a material that is transparent to magnetic fields.

The body (e.g. μ-metal body) of the component underlying the cold sprayed coating of electrically conductive and nonmagnetic material preferably has a high relative magnetic permeability. Relative magnetic permeability is a measure of how readily a material responds to an applied magnetic field. A material with high permeability has lower magnetic reluctance than a material with low permeability. Magnetic materials of this type provide a low reluctance path for the magnetic field to follow, rather than a higher reluctance path, such as that of air. By way of comparison, air is used as a standard, so that relative permeability of a material is conventionally expressed relative to that of air, at a given frequency. Air has a relative permeability of 1 at a frequency of 1 kHz, while certain materials may exhibit a relative permeability that is from about 5,000 to as much as 250,000 or more, at a frequency of 1 kHz. Preferably, the body of the component underlying the cold sprayed coating has a relative magnetic permeability of about 70,000 or greater, such as a relative magnetic permeability of about 350,000 and even greater. In a preferred embodiment, the body of the component has a relative magnetic permeability of about 80,000 to 100,000. Preferably the body of the component is made entirely of a μ-metal, such as a nickel-iron alloy, wherein the alloy can further include materials such as, but not limited to, molybdenum, copper, and chromium. For example, in an embodiment the μ-metal can contain about 75% nickel, 20% iron, and 5% molybdenum.

The electrically conductive and nonmagnetic coating is preferably cold sprayed on a surface of the body, such as a μ-metal body, to a thickness great enough such that the coating can support a RF current flowing therethrough. In this manner, the cold sprayed coating of the component can form part of a RF path in the plasma processing apparatus, wherein resistive power loss due to the high magnetic permeability of the body of the component underlying the cold sprayed coating is reduced, while the body of the component can still function as a magnetic shield. For example, magnetic shielding panels made of μ-metal can form a box which surrounds a vacuum chamber of the plasma processing apparatus wherein the cold sprayed coating is on an interior facing surface of the box formed by the magnetic shielding panels. In this manner, external magnetic fields outside of the box cannot enter the box and the cold spray coating can support RF currents circulating in the chamber without the RF current suffering from energy dissipation which would occur if the RF current were to circulate on the magnetic shielding panels alone.

To support the RF current, the coating of electrically conductive and nonmagnetic material is preferably cold sprayed on the surface of the body of the component, wherein the coating has a thickness greater than the skin depth (penetration depth) of a desired RF current to flow therethrough. More preferably, the cold sprayed coating of the component has a thickness great enough such that the desired RF current flowing therethrough does not penetrate through the coating of the component and enter the underlying body due to the phenomenon known as the skin effect, as explained below. For example, the cold sprayed coating is preferably thick enough to allow a current of about of 400 kHz, 2 MHz, 13.56 MHz, 27 MHz, or 60 MHz to flow therethrough without the current penetrating through the coating and entering the body of the component.

Skin effect is the tendency for an alternating current to concentrate near the outer part or “skin” of a conductor. With the alternating current, the current is displaced more and more to the surface as the frequency increases. The depth of the current as it is displaced to the surface of the conductor is known as the skin depth.

A mathematical description of skin effect can be derived from Maxwell's equations, for simple shapes, including cylindrical, tubular and flat conductors. For example, for a plane conductor carrying a sinusoidal alternating current, the current density is a maximum at the surface and its magnitude decreases exponentially with distance into the conductor. The skin depth or penetration depth δ is frequently used in assessing the results of skin effect. More specifically, skin depth is the depth below the conductor surface at which the current density has decreased to 1/e (approximately 37%) of its value at the surface and is given by Equation 1, shown below, wherein p is the resistivity of the conductor, Ω is the angular frequency of the current, and μ is the absolute magnetic permeability of the conductor. This concept applies to plane solids, but can be extended to other shapes provided the radius of curvature of the conductor surface is appreciably greater than δ.

δ=(2p/ωμ)^{-1/2} Equation 1

The cold sprayed electrically conductive and nonmagnetic coating is preferably formed on a surface, such as an interior facing surface, or alternatively on each exposed surface, of the body of the component such that its thickness is greater than the skin depth (δ) of a RF current flowing thereon. More preferably, the coating is formed on the body of the component such that its thickness is about three times or greater than the skin depth (i.e. >3δ) of a RF current flowing thereon. The cold sprayed electrically conductive and nonmagnetic coating can be formed from aluminum, titanium, tantalum, zirconium, copper, stainless steel, or alloys or mixtures thereof. The cold sprayed electrically conductive and nonmagnetic coating can be formed on each exposed surface of the body of the component such as each exterior surface, and interior surfaces that define a hole, cavity, or aperture, for example.

Components which include the cold sprayed coating of electrically conductive and nonmagnetic material can be used in apparatuses for performing various processes including plasma etching of semiconductor substrates and deposition of materials (e.g., ALD, PECVD, PEPVD, and the like) used for manufacturing various substrates including, e.g., semiconductor substrates, flat panel display substrates, and the like. Depending on the type and construction of an apparatus, the component(s) which include the cold spray coating of electrically conductive and nonmagnetic material on the surface of the body, such as a μ-metal body, can be a grounded component, form part of a RF path within the vacuum chamber, or be electrically isolated such that the cold spray coating may become RF hot during processing, such as to reduce byproduct deposition on an outer surface of the cold sprayed coating during plasma processing.

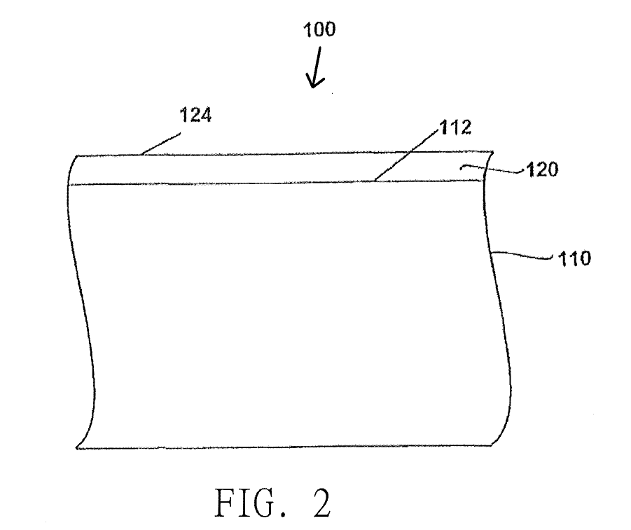

A cross section of a component 100 according to an exemplary embodiment is shown in FIG. 2. As shown, the component 100 includes a body 110 which has a surface 112 and a cold sprayed coating 120 of electrically conductive and nonmagnetic material is on the surface 112 such that it forms an outer surface 124 of the component 100. Preferably each exposed external and/or internal surface of the body 110 includes the cold sprayed coating 120 such that the cold sprayed coating forms the entire outer surface of the component. In an alternate embodiment, each surface of the body 110 wherein RF current is desired to flow through may include the cold sprayed coating 120. In an embodiment, the surface 112 of the body 110 to be cold sprayed can be roughened. In further preferred embodiments, the surface 112 may be polished or machined. In alternate preferred embodiments, the surface 112 may undergo a degreasing process before the cold sprayed coating 120 of electrically conductive and nonmagnetic material is formed thereon.

The component 100 which includes the cold sprayed coating 120 of electrically conductive and nonmagnetic material is preferably formed by cold spraying an electrically conductive and nonmagnetic metal or alloy onto the surface 112 of the body 110. Cold spraying is a kinetic spray process utilizing supersonic jets of compressed gas to accelerate near-room temperature powder particles (such as, preferably high purity aluminum, or alternatively tantalum) at high velocities, wherein the particles traveling at speeds between about 300 to 1,500 m/sec impact with the body of the component (here, the ferromagnetic or μ-metal body or other product being cold spray coated) to create a coating. In this manner, coatings can be formed on a body which has a high relative magnetic permeability, such as a μ-metal body, without affecting the magnetic shielding properties of the body previously caused by high temperatures needed in previous coating techniques such as thermal spraying. In one embodiment, the particles plastically deform and consolidate on the body upon impact. Cold spray may also be referred to as gas dynamic spray, supersonic spray, and/or kinetic spray. The basis of the cold spray process is the gas-dynamic acceleration of particulates (from high purity metal powders) to at high velocities (300-1500 m/sec), and hence high kinetic energies, so that solid-state plastic deformation and fusion occur on impact to produce dense coatings, with refined microstructure, without the feedstock material being significantly heated. For example, pure aluminum which has been wrought (fully worked) may have a Brinell Hardness Scale value between about 40 and 45, whereas cold sprayed pure aluminum may have a Brinell Hardness scale value between about 55 and 60. In one embodiment, this may be achieved using convergent-divergent de Laval nozzles, high pressures (up to 500 psi or 3.5 MPa) and flow rates (up to 90 m³/hr) of compressed gases such as helium, argon, or nitrogen. In another embodiment, the gases may be pre-heated to (below the melting point of many metals, preferably below 120° C., such as below about 80° C.) increase the velocity of the particles of the coating material. In one embodiment, the particles of the coating material may have a particle diameter ranging from about 1 to about 50 microns, and a particle density ranging from about 2.5 g/cm³ to about 20 g/cm³.

As the gas with which the metal powder forms a gas-powder mixture there is generally used an inert gas. Inert gas according to the embodiments herein includes, but is not limited to argon, helium, or relatively non-reactive nitrogen or mixtures of two or more thereof. In particular cases, air may also be used. If safety regulations are met, the use of mixtures of hydrogen with other gases can be considered and can be used advantageously due to hydrogen's extremely high sonic velocity. In fact hydrogen's sonic velocity is 30% greater than that of helium which in turn is approximately 3 times that of nitrogen. Air's sonic velocity is 344 m/s at 20° C. and 1 atmosphere (atm), while hydrogen with a lower molecular weight (about 2.016 as compared to air's molecular weight of 28.96) has a sonic velocity of 1308 m/s. For example, a gas mixture of helium and 4% hydrogen may be utilized.

The cold sprayed coating 120 of electrically conductive and nonmagnetic material is preferably formed of a material such as aluminum, titanium, tantalum, zirconium, copper, stainless steel, or alloys or mixtures thereof. The outer surface of the cold sprayed coating can preferably be annealed. In alternate embodiments, the outer surface of the cold sprayed coating can include a chromate conversion coating thereon, or the outer surface of the cold sprayed coating can include an outer oxide layer formed thereon.

In one embodiment, the cold spray coating may be performed in an inert chamber atmosphere, such as a vacuum chamber comprising argon, in order to prevent the oxidation of the component, for example a μ-metal component, that is to be sprayed. On the other hand, in another embodiment, the cold spray coating may be performed in air (e.g., in the room atmosphere), thereby allowing the spraying process to occur in a continuous, in-line fashion (i.e., without the component leaving the manufacturing line). An in-line spraying process may reduce the total amount of time and cost associated with the manufacture of the high purity spray coated components according to the teachings of one embodiment of the present disclosure.

The cold sprayed electrically conductive and nonmagnetic material forming the cold sprayed coating 120 can have a thickness of about 1 micrometer to about 10,000 micrometers. Preferably, the thickness of the cold sprayed coating 120 is substantially uniform over the surface 112 of the body 110 wherein the thickness of the cold sprayed coating 120 is greater than the skin depth of a RF current configured to flow therethrough, and more preferably greater than three times the skin depth of a RF current configured to flow therethrough. For example, the cold sprayed coating is preferably thick enough such that a RF current of about 400 kHz to 60 MHz, such as a RF current of 400 kHz, 2 MHz, 13.56 MHz, 27 MHz, or 60 MHz, can flow through the cold sprayed coating without the underlying body of the component causing unacceptable resistive power loss of the current. In embodiments wherein the component is exposed to process gas and/or plasma during processing, the cold sprayed electrically conductive and nonmagnetic coating preferably is formed of material which will not introduce contaminants in the vacuum chamber during processing wherein the coating has a purity of at least 99%, such as 99.5% or 99.7%, 99.9%, advantageously has a purity of at least 99.95%, based on metallic impurities, especially of at least 99.995% or of at least 99.999%, in particular preferably of at least 99.9995%. For example, aluminum having a purity of at least 99% may be cold sprayed on the body of the component wherein the aluminum cold sprayed coating is subsequently anodized.

The cold sprayed coating 120 preferably has good adhesion strength to the surfaces 112 of the body 110 (i.e. fails cohesively). Preferably, the cold sprayed coating 120 has a sufficiently-high adhesive bond strength to the surface(s) 112 of the body 110 on which the coating is formed such that when a tensile bond strength test is performed on the component 100, the cold sprayed electrically conductive and nonmagnetic coating fails cohesively (i.e., in the component bulk of the component) and not adhesively (i.e., at the body/coating interface).

In order to ensure good adhesion of the cold sprayed electrically conductive and nonmagnetic coating to the body 110, the surface 112 should be thoroughly cleaned from oxide scale and/or grease, prior to cold spraying. This cleaning can be carried out by agitating the body 110 in a solution of dilute hydrochloric acid, or sulfuric acid, or in a degreasing solvent before applying the cold sprayed coating 120.

Although the component which includes the cold sprayed electrically conductive and nonmagnetic coating is applicable to any type of component having a body which has a relative magnetic permeability of about 70,000 or greater, for ease of illustration, the coating will be described in more detail with reference to the apparatus described in commonly-assigned U.S. Pat. No. 8,025,731, which is incorporated herein by reference in its entirety.

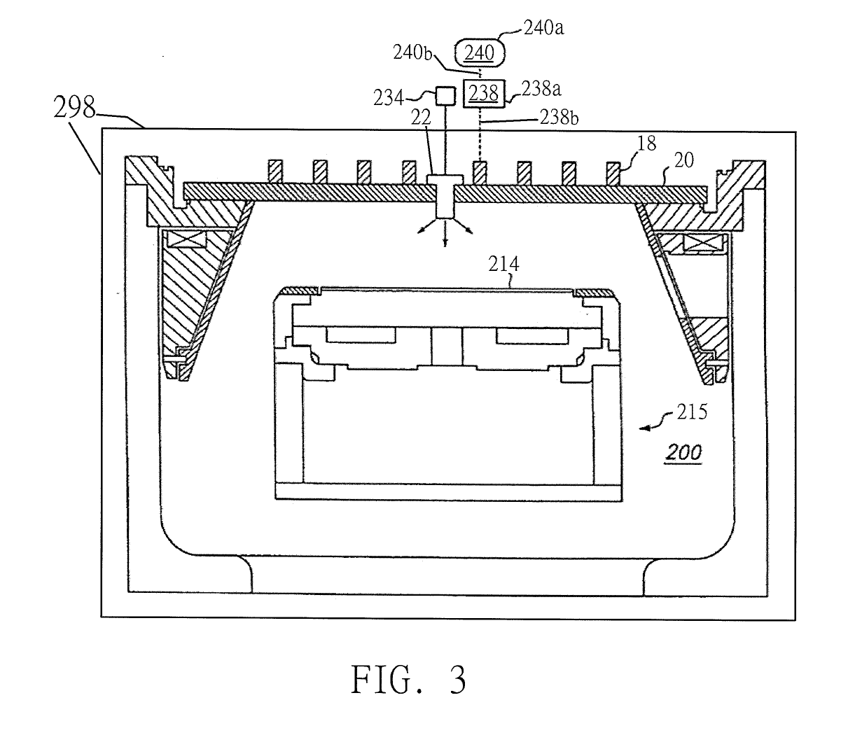

FIG. 3 illustrates an embodiment of an inductively coupled plasma processing apparatus wherein embodiments of components disclosed herein may be included. The inductively coupled plasma processing apparatus can include a vacuum chamber 200. The vacuum chamber 200 includes a lower electrode assembly 215 for supporting a substrate 214 in the interior of the vacuum chamber 200. A dielectric window 20 forms a top wall of vacuum chamber 200. Process gases are injected to the interior of the vacuum chamber 200 through a gas injector 22. A gas source 234 supplies process gases to the interior of the vacuum chamber 200 through gas injector 22.

Once process gases are introduced into the interior of vacuum chamber 200, they are energized into a plasma state by an antenna 18 supplying energy into the interior of vacuum chamber 200. Preferably, the antenna 18 is an external planar antenna powered by a RF power source 240 and RF impedance matching circuitry 238 to inductively couple RF energy into vacuum chamber 200. However, in an alternate embodiment, the antenna 18 may be an external or embedded antenna which is nonplanar. An electromagnetic field generated by the application of RF power to planar antenna energizes the process gas in the interior of the vacuum chamber 200 to form a high-density plasma (e.g., 10⁹-10¹² ions/cm³) above substrate 214. During an etching process, the antenna 18 (i.e. a RF coil) performs a function analogous to that of a primary coil in a transformer, while the plasma generated in the vacuum chamber 200 performs a function analogous to that of a secondary coil in the transformer. Preferably, the antenna 18 is electrically connected to the RF impedance matching circuitry 238 by an electrical connector 238b (i.e. lead) and the RF power source 240 is electrically connected to the RF impedance matching circuitry 238 by an electrical connector 240b. Preferably magnetic shielding panels 238a and 240a respectively surround the RF impedance matching circuitry 238 and the RF power source 240 such as to reduce magnetic interference with the magnetic field formed by antenna 18. In a further embodiment, magnetic shielding panels 298 can surround the vacuum chamber 200, such that magnetic interference caused by Earth's magnetic field as well as motors, power supplies, transformers, RF matching circuitry, RF path members which support a RF current during processing, electrical connectors, and the like surrounding the vacuum chamber may be shielded from the vacuum region 200. Preferably the cold spray coating is formed on the interior facing surface of each of the magnetic shielding panels 298, 238a, and 240a.

Plasma chamber components such as magnetic shielding panels surrounding the vacuum chamber, motors, power supplies, transformers, as well as components such as hollow rods for housing electrical connectors and sensors, support members, and electrical connectors preferably include the body which has a high magnetic permeability, such as a μ-metal body, and the cold sprayed coating on the surface of the body. For example, magnetic shielding 238a surrounding the RF impedance matching circuitry 238, magnetic shielding 240a surrounding the RF power supply 240, magnetic shielding panels 298, and electrical connectors, such as electrical connectors 240b and 238b, preferably are formed from a body having high magnetic permeability, such as a μ-metal body, and a cold sprayed coating on a surface of the body such that the cold sprayed coating can support a RF current therethrough. Further components which have a body of high magnetic permeability such as a lower or upper assembly lift actuator, bellows, shafts, support members, and chamber tops and walls can include the cold sprayed coating. Preferably the magnetic shielding panels are planar, however in some embodiments, some magnetic shielding panels can include curved portions such that the curved portion can eliminate sharp corners between adjacent planar magnetic shielding panels. In this manner, the curved portions can provide a better magnetic field line path between adjacent planar magnetic shielding panels than what is possible when adjacent magnetic shielding panels are configured to have a sharp corner, for example a right angle, therebetween. In an embodiment, adjacent magnetic shielding panels can be configured to overlap.

Further, any other body in the semiconductor plasma processing apparatus having a μ-metal surface or a surface which has a relative magnetic permeability of about 70,000 or greater may also include the cold sprayed electrically conductive and nonmagnetic coating thereon to form a cold sprayed component wherein in a first embodiment the cold sprayed component is grounded, such that the electric field may be terminated at the surface of the component, or alternatively in a second embodiment, the component may not be grounded such that the cold sprayed surface of the component becomes RF hot.

While the invention has been described in detail with reference to specific embodiments thereof, it will be apparent to those skilled in the art that various changes and modifications can be made, and equivalents employed, without departing from the scope of the appended claims.

What is claimed is:

1. A semiconductor plasma processing apparatus, comprising:
a plasma processing chamber in which semiconductor components are processed;
a process gas source in fluid communication with the plasma processing chamber for supplying a process gas into the plasma processing chamber;
a RF energy source adapted to energize the process gas into the plasma state in the plasma processing chamber;
a vacuum port for exhausting process gas from the plasma processing chamber;
and at least one component wherein the component has a body which has a relative magnetic permeability of about 70,000 or greater and a cold sprayed electrically conductive and nonmagnetic coating on a surface of the body wherein the coating has a thickness greater than the skin depth of a RF current configured to flow therethrough during plasma processing.

2. The plasma processing apparatus of claim 1, wherein the cold sprayed electrically conductive and nonmagnetic coating:
(a) has a thickness of about three times or greater than the skin depth of a RF current configured to flow therethrough;
(b) is selected from the group consisting of aluminum, titanium, tantalum, zirconium, copper, stainless steel, alloys thereof, and mixtures thereof;
(c) has an outer surface which is annealed;
(d) has an outer surface which includes a chromate conversion coating thereon; and/or
(e) has an outer surface which includes an outer oxide layer formed thereon.

3. The plasma processing apparatus of claim 1, wherein the body of the component is:
(a) formed from a nickel-iron alloy;
(b) formed from a μ-metal;
(c) a magnetic shielding panel;
(d) a magnetic shielding hollow rod;
(e) a support member; and/or
(f) an electrical connector.

4. The plasma processing apparatus of claim 1, wherein the component is a magnetic shielding panel and
(a) the magnetic shielding panel is configured to overlap an adjacent magnetic shielding panel;
(b) the magnetic shielding panel includes a planar portion; and/or
(c) the magnetic shielding panel includes a curved portion.

5. The plasma processing apparatus of claim 1, wherein
(a) an interior facing surface of the body of the component comprises the cold sprayed coating; or
(b) each exposed surface of the body of the component comprises the cold sprayed coating.

6. The plasma processing apparatus of claim 1, wherein the body of the component has a relative magnetic permeability of about 80,000 to 100,000; or greater than 100,000.

7. A component of a semiconductor plasma processing apparatus, the component comprising:
a body which has a relative magnetic permeability of about 70,000 or greater; and
a cold sprayed electrically conductive and nonmagnetic coating on a surface of the body wherein the coating has a thickness greater than the skin depth of a RF current configured to flow therethrough during plasma processing.

8. The component of claim 7, wherein the cold sprayed electrically conductive and nonmagnetic coating:
(a) has a thickness of three times or greater than the skin depth of a RF current configured to flow therethrough;
(b) is selected from the group consisting of aluminum, titanium, tantalum, zirconium, copper, stainless steel, alloys thereof, and mixtures thereof
(c) has an outer surface which is annealed;
(d) has an outer surface which includes a chromate conversion coating thereon; and/or
(e) has an outer surface which includes an outer oxide layer formed thereon.

9. The component of claim 7, wherein the body of the component:
(a) has a relative magnetic permeability of about 80,000 to 100,000, or a magnetic permeability greater than 100,000;
(b) is formed from a nickel-iron alloy; and/or
(c) is formed from a μ-metal.

10. The component of claim 7, wherein the component is:
(a) a magnetic shielding panel;
(b) a magnetic shielding hollow rod;
(c) a support member; or
(d) an electrical connector.

11. The component of claim 7, wherein each exposed surface of the body of the component comprises the cold sprayed coating.

12. The component of claim 7, wherein the component is a magnetic shielding panel and
(a) the magnetic shielding panel is configured to overlap an adjacent magnetic shielding panel;
(b) the magnetic shielding panel includes a planar portion; and/or
(c) the magnetic shielding panel includes a curved portion.

13. A method of forming a component of a semiconductor plasma processing apparatus, the method comprising:
cold spraying an electrically conductive and nonmagnetic material on a surface of a body that has a relative magnetic permeability of about 70,000 or greater, wherein the coating is formed on the surface of the body such that the thickness of the coating is greater than the skin depth of a RF current configured to flow therethrough.

14. The method of claim 13, and
(a) annealing an outer surface of the cold sprayed electrically conductive and nonmagnetic coating;
(b) anodizing an outer surface of the cold sprayed electrically conductive and nonmagnetic coating; or
(c) applying a chromate conversion coating to the cold sprayed coating of electrically conductive and nonmagnetic material.

15. The method of claim 13, and cold spraying the electrically conductive and nonmagnetic material on each exposed surface of the body.

16. The method of claim 13, and cleaning the surface of the body from oxide scale and/or grease prior to cold spraying the electrically conductive and nonmagnetic material on the surface of the body.

17. The method of claim 16, wherein the cleaning is performed by:
(a) agitating the body in a solution of dilute hydrochloric acid;
(b) agitating the body in sulfuric acid; and/or
(c) agitating the body in a degreasing solvent.

18. A method of plasma processing a semiconductor substrate in the apparatus according to claim 1, comprising:
supplying the process gas from the process gas source into the plasma processing chamber;
supplying RF energy into the plasma processing chamber to generate plasma from the process gas; and
plasma processing a semiconductor substrate in the plasma processing chamber;
wherein RF current flows through the cold sprayed electrically conductive and nonmagnetic coating of the component.

19. The method of claim 18, wherein a RF current of 400 kHz, 2 MHz, 13.56 MHz, 27 MHz, or 60 MHz flows through the cold sprayed electrically conductive and nonmagnetic coating of the component.

20. The method of claim 18, wherein the processing comprises plasma etching the substrate or performing a deposition process.
